(19) United States
(12) Patent Application Publication
(10) Pub. No.: US 2026/0248006 A1
(43) Pub. Date: Aug. 20, 2026

(54) PACKAGE DEVICE

(71) Applicants: Innolux Corporation, Miaoli County (TW); nD-HI Technologies Lab, Inc., Taipei City (TW); Bridge Semiconductor Corporation, Taipei (TW)

(72) Inventors: Ho-Ming Tong, Taipei City (TW); Chih-Chao Chuang, Miaoli County (TW); Chun-Yu Chien, Miaoli County (TW); Wen-Chiang Lin, Taipei City (TW)

(73) Assignees: Innolux Corporation, Miaoli County (TW); nD-HI Technologies Lab, Inc., Taipei City (TW); Bridge Semiconductor Corporation, Taipei (TW)

(21) Appl. No.: 19/450,738

(22) Filed: Jan. 16, 2026

Related U.S. Application Data
(60) Provisional application No. 63/760,119, filed on Feb. 19, 2025.

(30) Foreign Application Priority Data
Dec. 19, 2025 (CN) 202511931880.9

(51) Int. Cl. H10W 70/68; H10W 70/60; H10W 74/10; H10W 74/47; H10W 90/15; H10W 90/22; H10W 70/09

(52) U.S. Cl. CPC H10W 70/682; H10W 70/611; H10W 74/121; H10W 74/473; H10W 90/15; H10W 90/22; H10W 70/09

(57) ABSTRACT

A package device includes a substrate, an embedded module, a first circuit structure, a second circuit structure, an electronic unit, and a connecting piece. The embedded module is disposed in an opening of the substrate and includes embedded components and metal stack layers. First sides of at least two of the embedded components are located on a same plane, and second sides thereof have different heights. The metal stack layers are disposed on the second sides of the embedded components. Sides of the metal stack layers relatively away from the embedded components are aligned with each other. The first and second circuit structures are respectively disposed on a first and a second surfaces of the substrate and are respectively electrically connected to the embedded components and the metal stack layers. The electronic unit and the connecting piece are respectively electrically connected to the first and the second circuit structures.

### CROSS-REFERENCE TO RELATED APPLICATION

This application claims the priority benefit of U.S. Provisional Application No. 63/760,119, filed on February 19, 2025 and China Application No. 202511931880.9, filed on December 19, 2025. The entirety of the above-mentioned patent application is hereby incorporated by reference herein and made a part of this specification.

### BACKGROUND

### Related Art

When multiple embedded components have different heights in an embedded module resulting in height differences, if a flat contact surface is not provided after packaging, the circuit structure subsequently formed thereon will be difficult to electrically connect with these embedded components, thereby reducing the electrical reliability of the overall package device.

### BRIEF DESCRIPTION OF THE DRAWINGS

FIG. 1 is a cross-sectional schematic view of a package device according to an embodiment of the present disclosure.

FIG. 2 to FIG. 4 are cross-sectional schematic views of manufacturing steps of an embedded module according to an embodiment of the present disclosure.

FIG. 5 is a top schematic view of the embedded module in FIG. 4.

FIG. 6 is a cross-sectional schematic view of a metal stack layer according to an embodiment of the present disclosure.

FIG. 7 to FIG. 10 are cross-sectional schematic views of various embedded modules according to various embodiments of the present disclosure.

### DESCRIPTION OF THE EMBODIMENTS

The disclosure may be understood through referring to the following detailed description in conjunction with the drawings. It should be noted that in order to facilitate the understanding by the reader and for the conciseness of the drawings, multiple drawings in the disclosure only depict a part of an electronic device, and specific elements in the drawings are not drawn according to actual scale. In addition, the number and the size of each element in the drawings are only for illustration and are not intended to limit the scope of the disclosure.

Throughout the specification and the appended claims of the disclosure, certain words are used to refer to specific elements. Persons skilled in the art should understand that electronic device manufacturers may refer to the same elements by different names. The disclosure does not intend to distinguish the elements with the same function but different names.

In the following specification and claims, words such as "containing" and "comprising" are open-ended words, which should be interpreted as "including but not limited to...".

In addition, relative terms such as "below" or "bottom portion" and "above" or "top portion" may be used in the embodiments to describe the relative relationship between an element and another element in the drawings. It should be understood that if a device in the drawings is flipped upside down, elements described as "below" will become elements described as "above".

In some embodiments of the disclosure, when a component or film layer is referred to “on”, “connection”, “bonding” and “joining”, another component or film layer, unless specifically defined, may refer to two structures that are directly in contact or may also refer to two structures that are not directly (indirectly) in contact, wherein there is another structure provided between the two structures. Furthermore, the term "coupling" includes the transfer of energy between two structures through means of direct or indirect electrical connection or the transfer of energy between two separate structures by means of mutual induction.

The terms "about", "equal to", "equivalent" or "same", "substantially", or "roughly" are generally interpreted as within 20% of a given value or range, or interpreted as within 10%, 5%, or 0.5% of the given value or range.

In the disclosure, the definition of roughness judgment may be observed by the SEM or the transmission electron microscope (TEM), etc, observing the surface undulation condition under appropriate magnification, and taking a unit length (for example, 10μm) sample to compare the undulation condition as the roughness range. Here, "appropriate magnification" means that at least one surface may have a roughness (Rz) or an average roughness (Ra) of at least 10 peaks and valleys visible under the field of view of such a magnification.

As used herein, the terms "film" and/or "layer" may refer to any continuous or discontinuous structure and material.

Although the terms first, second, third... may be used to describe various constituent elements, the constituent elements are not limited by the terms. The terms are only used to distinguish a single constituent element from other constituent elements in the specification.

Unless otherwise defined, all terms used herein have the same meaning as commonly understood by one of ordinary skill in the art to which this disclosure belongs. These terms, such as those defined in commonly used dictionaries, should be interpreted as having a meaning consistent with the related art and the background or context of the present disclosure, and should not be interpreted in an idealized or overly formal manner.

The electronic device of the present disclosure may include a power module, semiconductor device, semiconductor package device, display device, antenna device, sensing device, light-emitting device, or splicing device, but is not limited thereto. The electronic device may include a bendable electronic device. According to embodiments of the present disclosure, the provided manufacturing method of the electronic device may be applied to, for example, wafer-level package (WLP) or panel-level package (PLP) processes, and may adopt chip first processes or chip last/RDL first processes. The electronic device referred to in the present disclosure may include System on Package (SoC), System in Package (SiP), Antenna in package (AiP), Co-Packaged Optics (CPO), or combinations thereof, but is not limited thereto.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

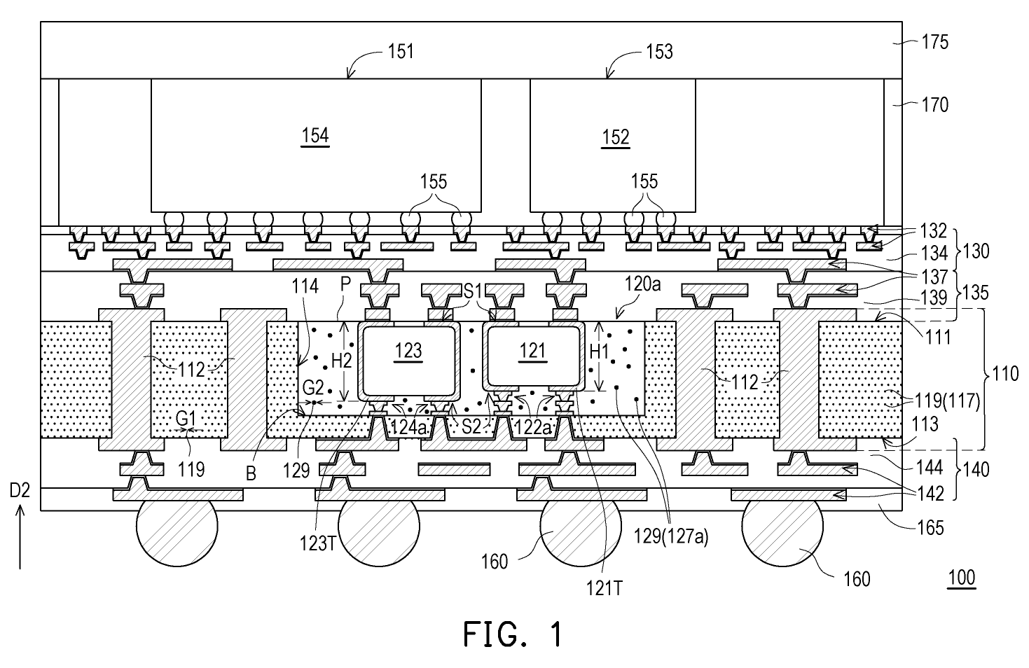

FIG. 1 is a cross-sectional schematic view of a package device according to an embodiment of the present disclosure. Referring to FIG. 1, in the present embodiment, the package device 100 includes a substrate 110, an embedded module 120a, a first circuit structure 130, a second circuit structure 140, electronic units 152, 154, and connecting pieces 160. The substrate 110 has a first surface 111 and a second surface 113 opposite to each other, and an opening 114 penetrating through the substrate 110 and connecting the first surface 111 and the second surface 113. The embedded module 120a is disposed in the opening 114 of the substrate 110, and the embedded module 120a includes a plurality of embedded components 121, 123 (two embedded components 121, 123 are schematically illustrated) and a plurality of metal stack layers 122a, 124a. The embedded components 121, 123 have a first side S1 and a second side S2 opposite to each other. The first side S1 of the embedded components 121, 123 is located on the same plane P, while the second side S2 of the embedded components 121, 123 has different heights H1, H2 on the same plane P. The metal stack layers 122a, 124a are respectively disposed on the second side S2 of the embedded components 121, 123 and are electrically connected to the electrodes 121T, 123T of the corresponding embedded components 121, 123. In an embodiment, the metal stack layers 122a, 124 may be aligned with the bottom surface of the opening 114. The first circuit structure 130 is disposed on the first surface 111 of the substrate 110 and is electrically connected to the embedded components 121, 123. The second circuit structure 140 is disposed on the second surface 113 of the substrate 110 and is electrically connected to the metal stack layers 122a, 124a. The electronic units 152, 154 are disposed on the first circuit structure 130 and are electrically connected to the first circuit structure 130. The connecting pieces 160 are disposed on the second circuit structure 140 and are electrically connected to the second circuit structure 140.

In the present embodiment, the substrate 110 further includes conductive vias 112 penetrating through the substrate 110. In an embodiment, a portion of the conductive vias 112 may extend to the first surface 111 and the second surface 113, wherein both ends of the conductive vias 112 are electrically connected to the first circuit structure 130 and the second circuit structure 140, respectively. In an embodiment, the conductive vias 112 do not extend to the surface of the substrate 110. In an embodiment, through holes may be formed in the substrate 110 by laser or mechanical drilling, then, electroplated metal layers are formed in the through holes and on the first surface 111 and the second surface 113 of the substrate 110 by electroplating, and thereafter, the electroplated metal layers are patterned to form the conductive vias 112. In an embodiment, conductive pillars may be implanted in the through holes, and then organic material may be provided to fill the gaps between the conductive pillars and the through holes to complete the conductive via structure. In an embodiment, the conductive vias 112 may be hollow conductive via structures, wherein the conductive vias 112 may be selectively filled with materials, such as epoxy or heat dissipation materials, such as graphite or silver nanoparticles, but not limited thereto. Furthermore, the substrate 110 further includes a first encapsulant 117 to cover the embedded module 120a and the conductive vias 112. The first encapsulant 117 may include a first filler 119, wherein the material of the first filler 119 is, for example, epoxy, polyimide, siloxane polymer, silicon oxide (SiOx), aluminum oxide (Al₂O₃), or other suitable materials. In an embodiment, the particle size G1 (such as diameter) of the first filler 119 is 3 micrometers to 60 micrometers.

Furthermore, the embedded module 120a is disposed within the opening 114 of the substrate 110. The first side S1 of the embedded components 121, 123 is located on the same side, or may be aligned with the first surface 111 of the substrate 110 or located on the plane P. For example, the second side S2 of the embedded component 121 has a height H1 on the same plane P, and the second side S2 of the embedded component 123 has a height H2 on the same plane P, wherein the height H2 is greater than H1 (i.e., H2>H1), meaning that the embedded components 121, 123 have different heights. In an embodiment, the embedded components 121, 123 are, for example, Surface Mounted Devices (SMD). In an embodiment, the embedded components 121, 123 may be, for example, active components or passive components. Active components are, for example, transistors, integrated circuits, or diodes, while passive components include resistors, capacitors, inductors, transformers, filters, and oscillators, but not limited thereto. The present disclosure reduces electrical anomalies by disposing the metal stack layers 122a, 124a to enable the embedded components 121, 123 of different heights to have contact planes of equal height. Here, each of the metal stack layers 122a, 124a refers to at least two metal portions of different dimensions stacked on each other, wherein the dimensions include length, width, and height. In an embodiment, the material of the metal stack layers 122a, 124a includes gold, copper, silver, aluminum, or other suitable conductive materials.

In addition, the embedded module 120a of the present embodiment further includes a second encapsulant 127a to cover the embedded components 121, 123 and the metal stack layers 122a, 124a. In an embodiment, the second encapsulant 127a may include a second filler 129, wherein the material of the second filler 129 may be similar to the first filler 119. In an embodiment, the particle size G2 (such as diameter) of the second filler 129 is 3 micrometers to 60 micrometers. In an embodiment, the coefficient of thermal expansion (CTE) of the first encapsulant 117 of the substrate 110 may be less than or equal to the CTE of the second encapsulant 127a of the embedded module 120a. In an embodiment, the particle size G1 of the first filler 119 of the first encapsulant 117 may be different from the particle size G2 of the second filler 129 of the second encapsulant 127a. In an embodiment, the particle size G1 of the first filler 119 of the first encapsulant 117 may be less than the particle size G2 of the second filler 129 of the second encapsulant 127a.

The first circuit structure 130 is configured on the first surface 111 of the substrate 110, and the first circuit structure 130 includes a first metal layer 132 and a first dielectric layer 134. In an embodiment, the first metal layer 132 is, for example, circuits, conductive vias, conductive blind vias, pads, or combinations thereof, and as long as it has a conductive function, it belongs to the first metal layer 132 described in the present disclosure. In an embodiment, the material of the first metal layer 132 may be, for example, copper, titanium, nickel, or combinations or alloys of the above materials, but is not limited thereto. In an embodiment, the material of the first dielectric layer 134 is, for example, photosensitive polyimide (PSPI), silicon dioxide (SiO₂), or silicon nitride (SiN_{X}), but is not limited thereto. In an embodiment, the first circuit structure 130 is, for example, a fine pitch redistribution layer, which may be electrically connected to electronic units 152, 154 through connecting components 155 or other bonding components. In an embodiment, the material of the connecting component 155 is, for example, copper, nickel, tin, silver, gold, gallium, or combinations thereof, but is not limited thereto.

The second circuit structure 140 is configured on the second surface 113 of the substrate 110, and the second circuit structure 140 includes a second metal layer 142 and a second dielectric layer 144. In an embodiment, the second metal layer 142 is similar to the first metal layer 132. In an embodiment, the material of the second dielectric layer 144 is, for example, PSPI or Ajinomoto build-up film (ABF), but is not limited thereto. In an embodiment, the second circuit structure 140 is, for example, a coarse pitch redistribution layer, which may be electrically connected to an external circuit, such as a circuit board, through connecting pieces 160 or other bonding components.

In an embodiment, a third circuit structure 135 may also be included between the first surface 111 of the substrate 110 and the first circuit structure 130, wherein the third circuit structure 135 includes a third metal layer 137 and a third dielectric layer 139. In an embodiment, the third metal layer 137 may be similar to the first metal layer 132. In an embodiment, the material of the third dielectric layer 139 is, for example, PSPI or ABF, but is not limited thereto. In an embodiment, the third circuit structure 135 is, for example, a coarse pitch redistribution layer.

It should be noted that the number of layers of the first metal layer 132, the second metal layer 142, and the third metal layer 137 are only schematically illustrated herein, but are not limited thereto, wherein the number of layers of the first metal layer 132, the second metal layer 142, and the third metal layer 137 may be different. In brief, the redistribution layer may include at least one dielectric layer and at least one metal layer alternately stacked along the second direction D2. Through the at least one dielectric layer and the at least one metal layer, circuit redistribution and/or enhancement of circuit fan-out or fan-in area may be achieved, or different electronic units may be electrically connected to each other through the redistribution layer. For example, the pitch of two adjacent contact pads at one end of the redistribution layer contacting the electronic unit may be less than or equal to the pitch of two adjacent contact pads at the other end of the redistribution layer away from the electronic unit, therefore the redistribution layer may adjust circuit fan-out conditions or electrically connect a circuit structure/electronic unit having a first pitch to a circuit structure/electronic unit having a second pitch, but is not limited thereto. The method of forming the redistribution layer may include using a Dual Damascene process, a photolithography etching process, a surface treatment process, a laser process, an electroplating process, a deposition process, a combination of the above processes, or other processes to form at least one dielectric layer and at least one metal layer. The surface treatment process includes roughening or activating the surface of the dielectric layer or the surface of the metal layer to enhance its adhesion capability, for example, by enhancing the surface roughness to enhance the bonding force with subsequent film layers.

Next, please refer to FIG. 1 again, the electronic units 152, 154 of the present embodiment are configured on the first circuit structure 130 and are electrically connected to the first circuit structure 130 through connecting components 155. In an embodiment, the electronic units 152, 154 may also be electrically connected to the outermost first metal layer 132 of the first circuit structure 130 through hybrid bonding (i.e., metal to metal, such as copper to copper direct bonding). In an embodiment, the electronic units 152, 154 may be, for example, known good die (KGD), diodes, antenna units, sensors, structures of semiconductor-related processes, or structures of semiconductor-related processes disposed on a substrate (for example, polyimide, glass, silicon substrate, or other suitable substrate materials), but are not limited thereto.

In addition, the package device 100 of the present embodiment further includes a support ring 170 configured on the first circuit structure 130. In an embodiment, the material of the support ring 170 is, for example, metal, but is not limited thereto. In an embodiment, the support ring 170 may also be used to balance the board warpage phenomenon generated after configuring the electronic units 152, 154 on the first circuit structure 130. For example, along the second direction D2, the warpage tendency of the support ring 170 may be opposite to the warpage tendency of the first circuit structure 130. In order to enhance the heat dissipation effect, the package device 100 of the present embodiment may also include a heat dissipation component 175 configured on the support ring 170 and directly contacting the back surfaces 151, 153 of the electronic units 152, 154 to enhance heat dissipation.

In addition, the connecting piece 160 of the present embodiment is directly configured on the outermost second metal layer 142 of the second circuit structure 140. In the present embodiment, the package device 100 further includes a solder mask 165 covering the peripheral surface of the outermost second metal layer 142 and exposing a portion of the second metal layer 142, and the connecting piece 160 directly contacts the second metal layer 142 exposed by the solder mask 165. Subsequently, the package device 100 may be electrically connected to an external circuit (such as a circuit board) through the connecting piece 160. In an embodiment, the connecting piece 160 is, for example, a solder ball.

That is to say, through the configuration of the above-mentioned metal stack layers 122a, 124a, the embedded components 121, 123 of different heights have contact planes of equal height, thereby enhancing the electrical reliability of the package device 100 of the present embodiment.

It should be noted here that the following embodiments adopt the component reference numerals and partial contents of the foregoing embodiments, wherein the same reference numerals are used to represent the same or similar components, and the description of the same technical contents is omitted. For the description of the omitted portions, reference may be made to the foregoing embodiments, and the following embodiments will not repeat the description.

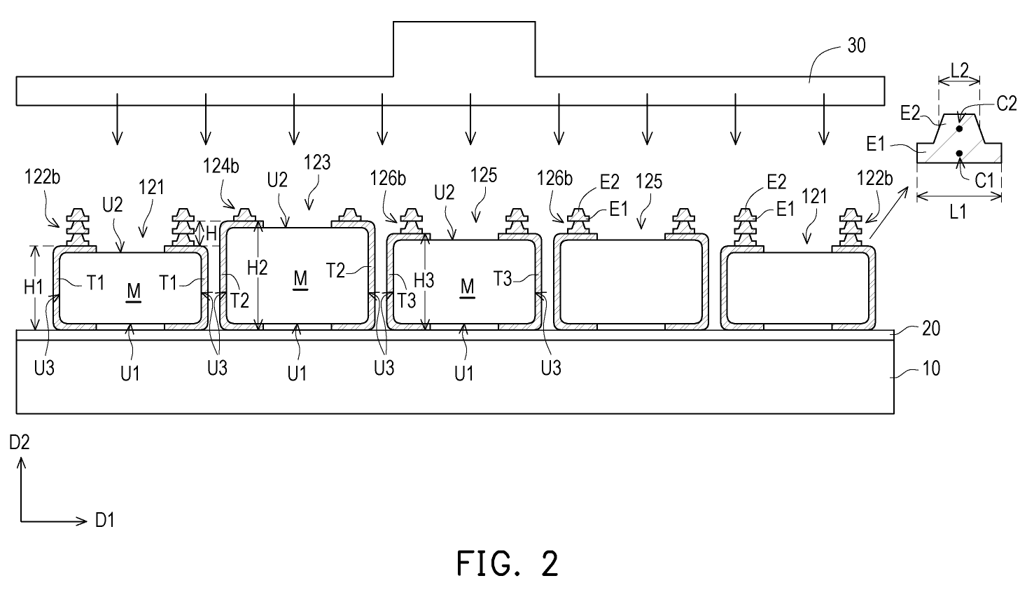

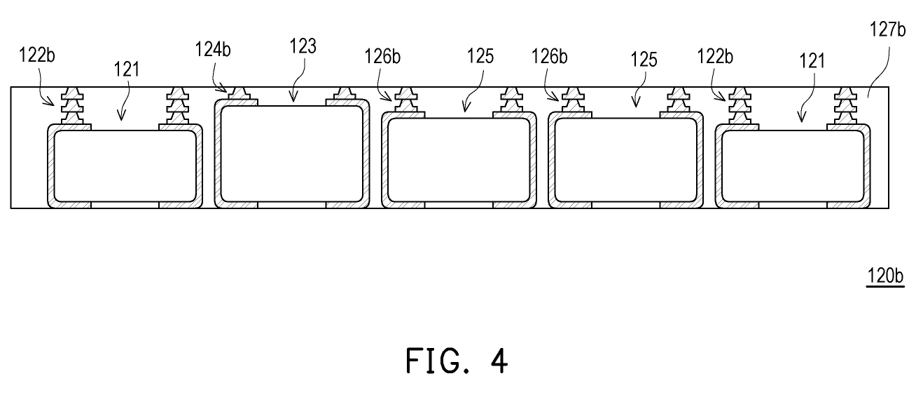

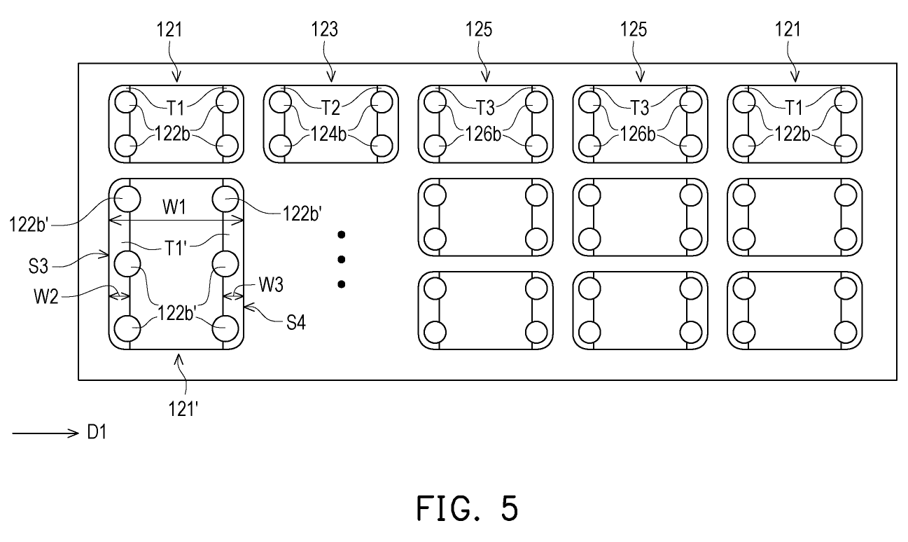

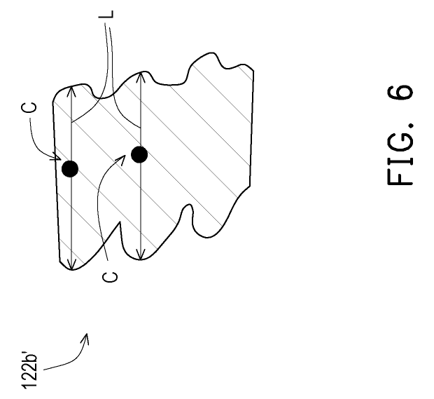

FIG. 2 to FIG. 4 are cross-sectional schematic views of manufacturing steps of an embedded module according to an embodiment of the present disclosure. FIG. 5 is a top view schematic of the embedded module of FIG. 4. FIG. 6 is a cross-sectional schematic view of a metal stack layer according to an embodiment of the present disclosure. Regarding the manufacturing method of the embedded module of the present embodiment, first, referring to FIG. 2, a carrier 10 is provided, wherein a release layer 20 is disposed on the carrier 10. Next, the embedded components 121, 123, 125 are configured on the carrier 10. Each of the embedded components 121, 123, 125 includes a body M and two connecting terminals T1, T2, T3 separated from each other. The body M has a top surface U1 and a bottom surface U2 opposite to each other, and a peripheral surface U3 connecting the top surface U1 and the bottom surface U2. The connecting terminals T1, T2, T3 are located on opposite sides of the body M and cover from the top surface U1 along the peripheral surface U3 to the bottom surface U2, wherein the connecting terminals T1, T2, T3 located on the top surface U1 directly contact the release layer 20 on the carrier 10, thus the connecting terminals T1, T2, T3 located on the top surface U1 are aligned with each other. In an embodiment, the embedded components 121, 123, 125 are, for example, SMD.

As shown in FIG. 2, the embedded components 121, 123, 125 respectively have different heights, that is, in the second direction D2 perpendicular to the first direction D1, the embedded component 121 has a height H1, the embedded component 123 has a height H2, and the embedded component 125 has a height H3, wherein the height H2 is greater than the height H3, and the height H3 is greater than the height H1, i.e., H2>H3>H1. The connecting terminals T1, T2 of the embedded components 121, 123 located on the bottom surface U2 have a height difference H. In an embodiment, the height difference H is between 5 micrometers and 200 micrometers, or between 50 micrometers and 150 micrometers.

Next, metal stack layers 122b, 124b, 126b are formed on the connecting terminals T1, T2, T3 located on the bottom surface U2 by wire bonding. In an embodiment, each metal stack layer 122b, 124b, 126b includes at least one metal stud, wherein each metal stud includes a first portion E1 and a second portion E2 located on the first portion E1. In an embodiment, the first portion E1 is, for example, a pad formed from a solder ball formed on the connecting terminals T1, T2, T3 after being micro-pressed by a capillary of a wire bonding device, and the second portion E2 is, for example, a wire formed by pulling and breaking upward from the solder ball through the capillary of the wire bonding device.

Next, please refer to FIG. 2 again, when forming a metal stud on the connecting terminals T1, T2, T3, because it is just formed through wire bonding, the appearance of the metal stud will have protrusions, which is not conducive to subsequently stacking metal studs thereon again. Therefore, each metal stud formed by wire bonding may be pressed by the pressed plate 30. The stacking quantity of metal studs in the metal stack layers 122b, 124b, 126b depends on the heights H1, H2, H3 of the embedded components 121, 123, 125, so as to achieve a flat (i.e., equal height) contact plane. In an embodiment, the metal stack layer 122b is, for example, formed with three metal studs through three wire bonding processes, the metal stack layer 124b is, for example, formed with one metal stud through one wire bonding process, and the metal stack layer 126b is, for example, formed with two metal studs through two wire bonding processes. That is to say, the metal stack layers 122b, 124b, 126b also respectively have different heights.

In an embodiment, the ratio of the second distance L2 of the second width center point C2 of the second portion E2 (i.e., upper layer structure) of each metal stack layer 122b, 124b, 126b in the first direction D1 to the first distance L1 of the first width center point C1 of the first portion E1 (i.e., lower layer structure) in the first direction D1 (ratio=L2/L1) is less than or equal to 10%, thereby ensuring that the mutually stacked metal studs still maintain structural and electrical connection after being pressed by the pressed plate 30.

Furthermore, please refer to FIG. 2 and FIG. 6 simultaneously, since the metal stack layers 122b, 122b' have undergone a flattening process by the pressed plate 30, in an embodiment, the metal stack layer 122b' may also deform. However, in the case of deformation, the distance L of the width center point C of each metal stud of the metal stack layer 122b' in the first direction D1 is less than or equal to 10 micrometers.

In addition, please refer to FIG. 2 and FIG. 5 simultaneously, the quantity of the metal stack layers 122b, 122b', 124b, 126b on each embedded component 121, 121', 123, 125 is determined by the dimension of each embedded component 121, 121', 123, 125 and the area of the connecting terminals T1, T1', T2, T3. In an embodiment, the dimension of the embedded component 121' is greater than the dimension of the embedded components 121, 123, 125, and the area of the connecting terminal T1' of the embedded component 121' is also greater than the area of the connecting terminals T1, T2, T3 of the embedded components 121, 123, 125, therefore metal stack layers 122b' with larger dimension (such as orthographic projection area) and greater quantity are disposed on the connecting terminal T1 of the embedded component 121', for example, six metal stack layers 122b' are disposed, but not limited thereto. In an embodiment, the dimension (such as orthographic projection area) of the metal stack layers on the same embedded component may have the same or different sizes. In an embodiment, the outer surfaces S3, S4 of the two connecting terminals T1' of the embedded component 121' are spaced apart by a distance W1 in the first direction D1, and the widths of the two connecting terminals T1, T2 in the first direction D1 are W2 and W3 respectively, and 0.1≦(W2+W3)/W1≦0.6, thereby enhancing the bonding force between the embedded component 122b' and the release layer 20.

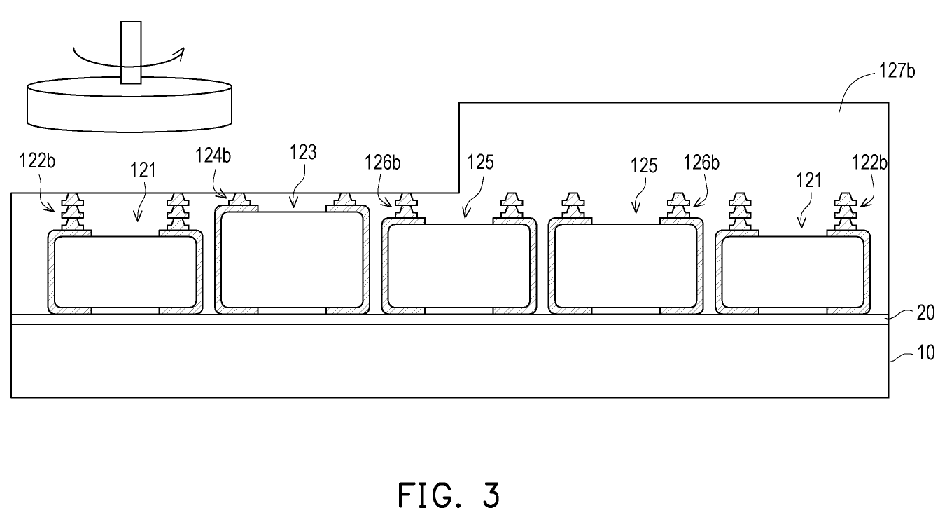

Next, please refer to FIG. 3, a second encapsulant 127b is formed on the release layer 20, wherein the second encapsulant 127b completely encapsulates the metal stack layers 122b, 124b, 126b and the embedded components 121, 123, 125. In an embodiment, the material of the second encapsulant 127b is, for example, an insulating material, which may include organic material or inorganic material, but not limited thereto. Afterwards, please refer to FIG. 3 and FIG. 4 simultaneously, a portion of the second encapsulant 127b is removed by grinding to expose the metal stack layers 122b, 124b, 126b, thereby forming the embedded module 120b with a flat contact surface as shown in FIG. 4.

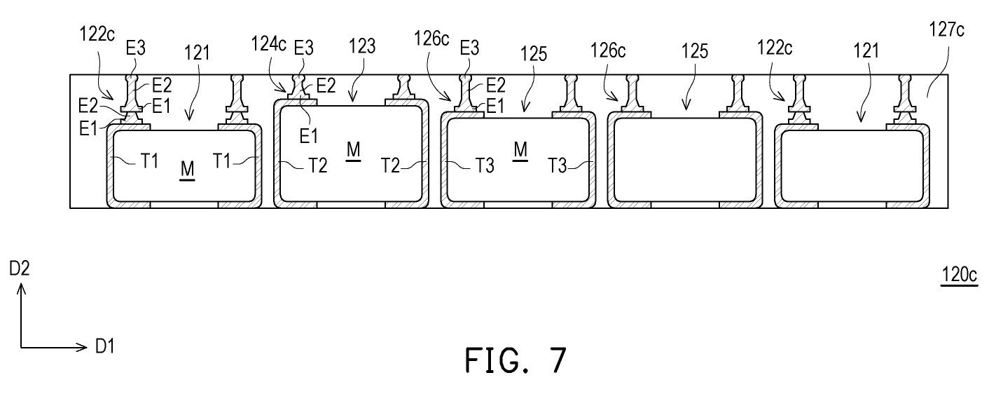

FIG. 7 is a cross-sectional schematic view of an embedded module according to another embodiment of the present disclosure. Please refer to FIG. 4 and FIG. 7 simultaneously, the embedded module 120c of the present embodiment is similar to the embedded module 120b of FIG. 4, the difference between both is: in the present embodiment, the metal stack layers 122c, 124c, 126c are at least one metal pillar formed by wire bonding, and each metal pillar includes a first portion E1, a second portion E2, and a third portion E3, wherein the second portion E2 is located between the first portion E1 and the third portion E3. In an embodiment, the first portion E1 is, for example, a pad formed by a solder ball formed on the connecting terminals T1, T2, T3, and then slightly pressed by a capillary of a wire bonding device, and the second portion E2 is, for example, a wire formed by pulling the solder ball from the capillary of the wire bonding device in a second direction D2 perpendicular to the first direction D1, and the third portion E3 is an arc-shaped pattern generated by deformation after the wire is pressed by the pressed plate 30 in FIG. 2. In an embodiment, the arc-shaped pattern of the third portion E3 may prevent the metal pillar from cracking during subsequent grinding of the second encapsulant 127c, which may enhance structural reliability.

It should be noted that the stacking number of the first portion E1 and the second portion E2 of the metal stack layer 122c may be determined based on the height difference of the embedded components 121, 123, 125. In an embodiment, the metal stack layer 122c is composed of two metal pillars stacked on each other, that is, including two first portions E1 and second portions E2 stacked on each other, and one third portion E3 stacked on the outermost second portion E2. In an embodiment, the metal stack layer 124c is composed of one metal pillar, that is, including one first portion E1, one second portion E2, and one third portion E3 stacked in sequence. In an embodiment, the metal stack layer 126c is composed of one metal pillar, that is, including one first portion E1, one second portion E2, and one third portion E3 stacked in sequence, wherein the length of the second portion E2 of the metal stack layer 126c in the second direction D2 is greater than the length of the second portion E2 of the metal stack layer 124c in the second direction D2.

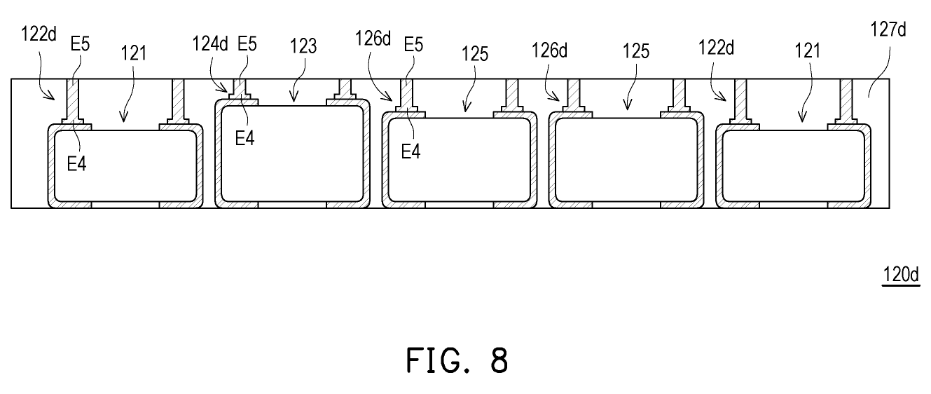

FIG. 8 is a schematic cross-sectional view of an embedded module according to another embodiment of the present disclosure. Please refer to FIG. 4 and FIG. 8 simultaneously, the embedded module 120d of the present embodiment is similar to the embedded module 120b of FIG. 4, the difference between both is: in the present embodiment, the metal stack layers 122d, 124d, 126d are, for example, metal pillars, wherein the metal pillars include a pad portion E4 and a column portion E5. In an embodiment, the metal stack layers 122d, 124d, 126d may be formed on the embedded components 121, 123, 125 by soldering. Then, the second encapsulant 127d completely covers the metal stack layers 122d, 124d, 126d and the embedded components 121, 123, 125. Afterwards, a portion of the second encapsulant 127d is removed by grinding to expose the column portion E5 of the metal stack layers 122d, 124d, 126d, thereby forming the embedded module 120d with a flat contact surface as shown in FIG. 8.

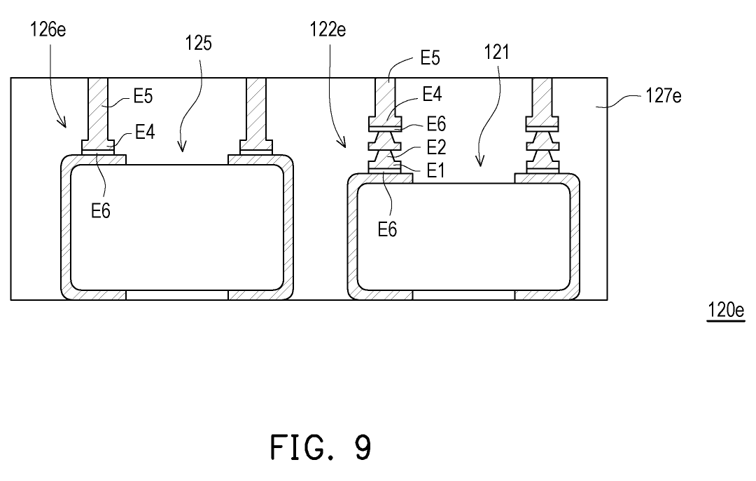

FIG. 9 is a schematic cross-sectional view of an embedded module according to another embodiment of the present disclosure. Please refer to FIG. 4 and FIG. 9 simultaneously, the embedded module 120e of the present embodiment is similar to the embedded module 120b of FIG. 4, the difference between both is: in the present embodiment, in addition to forming metal pillars including the first portion E1 and the second portion E2 by wire bonding, metal pillars including the pad portion E4 and the column portion E5 may also be selectively soldered on the embedded components 121, 125. Furthermore, in order to enhance the bonding force between different metal layers, an auxiliary layer E6 may also be disposed between the embedded component 125 and the pad portion E4 of the metal pillar, between the embedded component 121 and the first portion E1 of the metal pillar, and between the second portion E2 of the metal pillar and the pad portion E4 of the metal pillar. Then, the second encapsulant 127e completely covers the metal stack layers 122e, 126e and the embedded components 121, 125. Afterwards, a portion of the second encapsulant 127e is removed by grinding to expose the column portion E5 of the metal stack layers 122e, 126e, thereby forming the embedded module 120e with a flat contact surface as shown in FIG. 9.

In an embodiment, the metal stack layer 126e is composed of an auxiliary layer E6 and a metal pillar soldered on the auxiliary layer E6 and including the pad portion E4 and the column portion E5. In an embodiment, the metal stack layer 122e is composed of an auxiliary layer E6, two metal pillars formed by wire bonding and sequentially stacked (two first portions E1 and two second portions E2 alternately stacked), an auxiliary layer E6, and a metal pillar soldered on the auxiliary layer E6 and including the pad portion E4 and the column portion E5. In an embodiment, the material of the auxiliary layer E6 is different from the material of the metal pillar. In an embodiment, the material of the auxiliary layer E6 is, for example, tin, nickel, gold, gallium, combinations of the above, or other suitable metals.

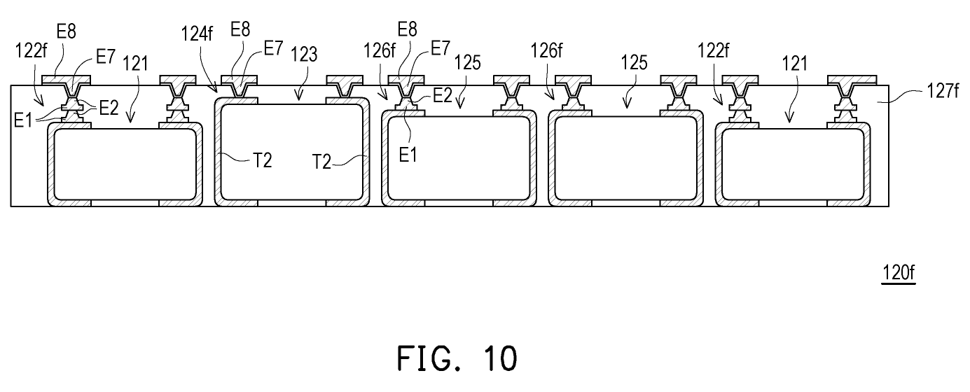

FIG. 10 is a schematic cross-sectional view of an embedded module according to another embodiment of the present disclosure. Please refer to FIG. 4 and FIG. 10 simultaneously, the embedded module 120f of the present embodiment is similar to the embedded module 120b of FIG. 4, and the difference between both is: in the present embodiment, in addition to first forming metal pillars including the first portion E1 and the second portion E2 through wire bonding to enable the embedded components 121, 125 and the embedded component 123 of different heights to form a flat contact surface, after forming the second encapsulant 127f that completely encapsulates the embedded components 121, 123, 125 and the metal pillars, blind vias exposing the second portion E2 of the metal pillars and exposing the connecting terminals T2 of the embedded component 123 may also be formed in the second encapsulant 127f by laser drilling or mechanical drilling. Then, a plating seed layer is formed in the blind vias and on the outer surface of the second encapsulant 127f by sputtering or chemical deposition, and thereafter, conductive material is electroplated using the plating seed layer and patterned to form conductive blind vias E7 connecting the second portion E2 and conductive circuits E8 located on the outer surface of the second encapsulant 127f. In other words, the present embodiment does not perform a grinding process, but exposes the metal pillars through drilling.

It should be noted that the stacking number of the first portion E1 and the second portion E2 of the metal pillars may be determined based on the height difference of the embedded components 121, 125. In one embodiment, the metal stack layer 122f is composed of, for example, two metal pillars stacked with each other (i.e., two first portions E1 and two second portions E2 alternately stacked), conductive blind vias E7 stacked on the outermost second portion E2, and conductive circuits E8 connecting the conductive blind vias E7 and located on the outer surface of the second encapsulant 127f. In one embodiment, the metal stack layer 124f is composed of, for example, conductive blind vias E7 connecting the connecting terminals T2 and conductive circuits E8 connecting the conductive blind vias E7 and located on the outer surface of the second encapsulant 127f. In one embodiment, the metal stack layer 126f is composed of, for example, one metal pillar (i.e., one first portion E1 and one second portion E2), conductive blind vias E7 stacked on the second portion E2, and conductive circuits E8 connecting the conductive blind vias E7 and located on the outer surface of the second encapsulant 127f.

In summary, in the embodiments of the present disclosure, the first sides of at least two embedded components are located on the same plane while the second sides have different heights on the same plane, wherein the metal stack layers are configured on the second sides of the embedded components, and the sides of the metal stack layers relatively far from the embedded components are flush with each other. That is to say, the present disclosure, through the disposition of the metal stack layers, enables embedded components of different heights to have contact planes of the same height, thereby improving the electrical reliability of the package device of the present disclosure.

Finally, it should be noted that: the above embodiments are only used to describe the technical solutions of the present invention, and not to limit it; although the present invention has been described in detail with reference to the foregoing embodiments, those of ordinary skill in the art should understand that: they may still modify the technical solutions described in the foregoing embodiments, or perform equivalent replacement, recombination, or mixing of some or all of the technical features therein; and these modifications or replacements do not cause the essence of the corresponding technical solutions to depart from the scope of the technical solutions of the embodiments of the present invention.

What is claimed is:

1. A package device, comprising:
a substrate having a first surface and a second surface opposite to each other, and an opening penetrating through the substrate and connecting the first surface and the second surface;
an embedded module disposed in the opening of the substrate, and comprising a plurality of embedded components and a plurality of metal stack layers, the embedded components having a first side and a second side opposite to each other, the first sides of at least two embedded components of the embedded components being located on a same plane, and the second sides of the at least two embedded components of the embedded components having different heights on the same plane, and the metal stack layers being respectively disposed on the second sides of the embedded components and respectively electrically connected to the corresponding embedded components, and sides of the metal stack layers relatively away from the embedded components being aligned with each other;
a first circuit structure disposed on the first surface of the substrate and electrically connected to the embedded components;
a second circuit structure disposed on the second surface of the substrate and electrically connected to the metal stack layers;
an electronic unit disposed on the first circuit structure and electrically connected to the first circuit structure; and
a connecting piece disposed on the second circuit structure and electrically connected to the second circuit structure.

2. The package device according to claim 1, wherein each of the embedded components comprises a body and two connecting terminals separated from each other, the body having a top surface and a bottom surface opposite to each other and a peripheral surface connecting the top surface and the bottom surface, the two connecting terminals being located on opposite sides of the body and covering from the top surface along the peripheral surface to the bottom surface, the two connecting terminals located on the top surface being aligned with each other, the metal stack layers being disposed on the two connecting terminals located on the bottom surface, and the two connecting terminals of the at least two embedded components located on the bottom surface having a height difference, and the height difference being between 5 micrometers and 200 micrometers.

3. The package device according to claim 2, wherein outer surfaces of the two connecting terminals are spaced apart by a distance W1 in a first direction, and widths of the two connecting terminals in the first direction are W2 and W3 respectively, and 0.1≦(W2+W3)/W1≦0.6.

4. The package device according to claim 1, wherein the embedded module further comprises a plurality of auxiliary layers disposed between the metal stack layers and the embedded components.

5. The package device according to claim 1, wherein the substrate further comprises a first encapsulant to cover the embedded module, and the embedded module further comprises a second encapsulant to cover the embedded components and the metal stack layers.

6. The package device according to claim 5, wherein a coefficient of thermal expansion of the first encapsulant is less than or equal to a coefficient of thermal expansion of the second encapsulant.

7. The package device according to claim 5, wherein the first encapsulant comprises a first filler, and the second encapsulant comprises a second filler, and a particle size of the first filler is different from a particle size of the second filler.

8. The package device according to claim 7, wherein a material of the first filler comprises epoxy, polyimide, siloxane polymer, SiOₓ or Al₂O₃.

9. The package device according to claim 7, wherein the particle size of the first filler is 3 micrometers to 60 micrometers.

10. The package device according to claim 7, wherein the particle size of the first filler is less than the particle size of the second filler.

11. The package device according to claim 1, wherein each of the metal stack layers comprises a lower structure and an upper structure, and a ratio of a second distance of a second width center point of the upper structure in a first direction to a first distance of a first width center point of the lower structure in the first direction is less than or equal to 10%.

12. The package device according to claim 1, wherein a distance of a center point of a width of each of the metal stack layers in a first direction is less than or equal to 10 micrometers.

13. The package device according to claim 1, wherein the substrate further comprises a conductive via passing through the substrate and extending onto the first surface and the second surface, wherein the conductive via is electrically connected to the first circuit structure and the second circuit structure.

14. The package device according to claim 1, wherein each of the embedded components comprises an active component or a passive component.

15. The package device according to claim 1, wherein the first circuit structure is a fine pitch redistribution structure layer, and the second circuit structure is a coarse pitch redistribution structure layer.

16. The package device according to claim 1, further comprising:
a third circuit structure disposed between the first surface of the substrate and the first circuit structure.

17. The package device according to claim 1, further comprising:
a support ring disposed on the first circuit structure.

18. The package device according to claim 17, wherein a material of the support ring comprises metal.

19. The package device according to claim 17, further comprising:
a heat dissipation component disposed on the support ring and directly contacting a back surface of the electronic unit.

20. The package device according to claim 1, wherein the first side of each of the embedded components is located on a same side, or is aligned with the first surface of the substrate or located on the plane.
